(19) United States
(12) Patent Application Publication
(10) Pub. No.: US 2026/0349030 A1
(43) Pub. Date: Nov. 5, 2026

(54) CHIP AND CHIP TESTING METHOD

(71) Applicant: SANECHIPS TECHNOLOGY CO., LTD., Shenzhen, Guangdong (CN)

(72) Inventors: Keqing OUYANG, Shenzhen, Guangdong (CN); Minqiang PENG, Shenzhen, Guangdong (CN); Jitong ZHOU, Shenzhen, Guangdong (CN); Guohua ZHOU, Shenzhen, Guangdong (CN); Youfa WU, Shenzhen, Guangdong (CN)

(21) Appl. No.: 19/485,715

(22) PCT Filed: May 20, 2024
(86) PCT No.: PCT/CN2024/094137

§ 371 Date: Nov. 19, 2025

(30) Foreign Application Priority Data
May 31, 2023 (CN) 202310638057.3

(51) Int. Cl. G01R 31/317

(52) U.S. Cl. CPC G01R 31/31722

(57) ABSTRACT

A chip includes: a plurality of structurally identical multiplexing modules, each of which has a module input and a module output; a test input pin connected to module inputs of the multiplexing modules and configured to input a test signal into the module inputs; a comparison module provided with an input connected to module outputs of the multiplexing modules, and an output, the comparison module being configured to receive and compare result signals output at the module outputs of the multiplexing modules for the test signal, and output, at the output of the comparison module, a comparison result indicating whether the result signals of all the module outputs connected thereto are completely the same; and a comparison output pin connected to the output of the comparison module and configured to output a signal representing the comparison result.

### CROSS-REFERENCE TO RELATED APPLICATIONS

This application claims priority to Chinese Patent Application No. 202310638057.3 filed with the CNIPA on May 31, 2023, the entire contents of which are incorporated hereby by reference.

### TECHNICAL FIELD

The present disclosure relates to, but is not limited to, the technical field of chip testing.

### BACKGROUND

With the evolution of the chip preparation process, more and more components of increasingly smaller sizes and larger scales are provided in the chips, which increases the defect rate. To screen out faulty chips and improve the product quality, chip testing is required.

However, to detect a chip including a large number of multiplexing modules (e.g., multiplexing cores), a large number of pins are required for the chip, and the testing process is complex.

### SUMMARY

The present disclosure provides a chip and a chip testing method.

In a first aspect, an embodiment of the present disclosure provides a chip, including: a plurality of structurally identical multiplexing modules, each of which has a module input and a module output; a test input pin connected to module inputs of the multiplexing modules and configured to input a test signal into the module inputs; a comparison module provided with an input connected to module outputs of the multiplexing modules, and an output, wherein the comparison module is configured to receive and compare result signals output at the module outputs of the respective multiplexing modules for the test signal, and output, at the output of the comparison module, a comparison result indicating whether the result signals of all the module outputs connected thereto are completely the same; and a comparison output pin connected to the output of the comparison module and configured to output a signal representing the comparison result.

In a second aspect, an embodiment of the present disclosure provides a chip testing method, wherein the chip includes a plurality of structurally identical multiplexing modules, each of which has a module input and a module output, and the method includes: acquiring a test signal, and synchronously transmitting the test signal to module inputs of the multiplexing modules; outputting, by each multiplexing module, a result signal at the module output of the multiplexing module for the test signal; comparing result signals at the module outputs of the multiplexing modules, and generating a comparison result indicating whether the result signals are completely the same; and outputting a signal representing the comparison result.

### BRIEF DESCRIPTION OF DRAWINGS

In the drawings of the embodiments of the present disclosure:

FIG. 1 is a block diagram of a chip according to an embodiment of the present disclosure;

FIG. 2 is a block diagram of a multiplexing module in a chip according to an embodiment of the present disclosure;

FIG. 3 is a block diagram of another chip according to an embodiment of the present disclosure;

FIG. 4 is a block diagram of another chip according to an embodiment of the present disclosure;

FIG. 5 is a circuit diagram of a comparison module in a chip according to an embodiment of the present disclosure;

FIG. 6 is a circuit diagram of another comparison module in a chip according to an embodiment of the present disclosure;

FIG. 7 is a flowchart of a chip testing method according to an embodiment of the present disclosure;

FIG. 8 is a flowchart of another chip testing method according to an embodiment of the present disclosure; and

FIG. 9 is a schematic diagram of an exemplary chip testing logic process according to an embodiment of the present disclosure.

### DETAIL DESCRIPTION OF EMBODIMENTS

To improve understanding of the technical solution of the present disclosure for those skilled in the art, the chip and the chip testing method provided in the embodiments of the present disclosure will be described below in detail in conjunction with the accompanying drawings.

The present disclosure will be described more sufficiently below with reference to the accompanying drawings, where the illustrated embodiments may be embodied in different forms. However, the present disclosure should not be construed as being limited to the embodiments set forth herein. Rather, these embodiments are provided so that the present disclosure will be thorough and complete, and will fully convey the scope of the present disclosure to those skilled in the art.

Accompanying drawings are provided for further understanding of the embodiments of the present disclosure and constitute a part of the specification. Hereinafter, these drawings are intended to explain the present disclosure together with the detailed embodiments, but should not be considered as a limitation to the present disclosure. The above and other features and advantages will become more apparent to those skilled in the art by describing the detailed embodiments with reference to the accompanying drawings.

The present disclosure may be described with reference to plan and/or sectional views in idealized representations of the present disclosure. Accordingly, the example illustrations may be modified in accordance with the manufacturing process and/or the tolerance.

The embodiments of the present disclosure and features thereof may be combined with each other as long as they are not contradictory.

The terminology used herein is for the purpose of describing specific embodiments only and is not intended to limit the present disclosure. As used in the present disclosure, the term “and/or” includes any and all combinations of one or more of the associated listed items. As used in the present disclosure, the singular forms “a”, “an” and “the” are intended to include the plural forms as well, unless the context clearly indicates otherwise. As used herein, the terms “comprise” and “consist of . . . ” specify the presence of the stated features, integers, steps, operations, elements, and/or components, but do not preclude the presence or addition of one or more other features, integers, steps, operations, elements, components, and/or groups thereof.

Unless otherwise defined, all terms (including technical and scientific terms) used in the present disclosure have the same meaning as commonly understood by one of ordinary skill in the art. It will be further understood that terms, such as those defined in commonly used dictionaries, should be interpreted as having a meaning that is consistent with their meaning in the context of the existing art and the present disclosure, and will not be interpreted in an idealized or overly formal sense unless expressly so defined in the present disclosure.

The present disclosure is not limited to the embodiments shown in the drawings, but includes modifications of configurations formed based on a manufacturing process. Therefore, the regions illustrated in the figures have schematic properties, and the shapes of the regions shown in the figures illustrate specific shapes of regions of elements, but are not intended to be limitative.

With the evolution of the chip preparation process (e.g., for logic chips, network chips, and the like), more and more components (e.g., transistors) of increasingly smaller sizes and larger scales are provided in the chips, which increases the defect (fault) rate, such as short circuits caused by bridging, erroneous connection of circuits at undesired positions (e.g., high or low levels), delays due to circuit defects, and the like.

To screen out faulty chips and improve the product quality, chip testing is a necessity.

However, the integrated circuit in the chip typically has a large scale, and the combinational logic and the sequential logic are very complex, making it difficult to directly detect or observe the components therein. In view of this, a specific test signal may be input to the chip, and then a result signal generated by the chip is analyzed to determine whether the structure of the chip is faulty.

Illustratively, a test pattern (a signal composed of a series of 0's and 1's) may be generated by automatic test pattern generation (ATPG) and input to the chip through an input pin, while a result pattern generated by the chip is obtained through an output pin. An automatic test equipment (ATE) compares and determines whether a standard pattern without any fault is the same as the actual result pattern, thereby determining whether the chip has a fault.

A large-scale chip often includes a plurality of structurally identical parts, i.e., a plurality of “multiplexing modules”, such as a plurality of logic cores (multiplexing cores). Due to the identical structure, these multiplexing modules may be tested by the same test signal (e.g., test pattern). In view of this, a shared-input technology may be employed, in which the same test signal is simultaneously input to a plurality of multiplexing modules through one input pin of a chip, so as to reduce the number of input pins and simplify the input of the test signal.

However, although the input test signal can be shared, different multiplexing modules are independent of each other, and therefore, result signals (e.g., result patterns) generated by operation of the respective multiplexing modules still need to be read out through different output pins, and compared with the standard result (e.g., standard pattern) respectively to determine whether each multiplexing module has a fault. Therefore, the above method still needs a large number of output pins provided for the chip, and the multiplexing modules still need to be detected and analyzed separately, resulting in a chip with a large total number of pins, a complex structure, and a complex testing process.

Moreover, the testing cost constitutes an important portion of the chip cost, and the time to market of the chip may be delayed due to the time consumed for the testing process. Therefore, the complex testing process may further increase the chip cost and influencing the marketability of the chip.

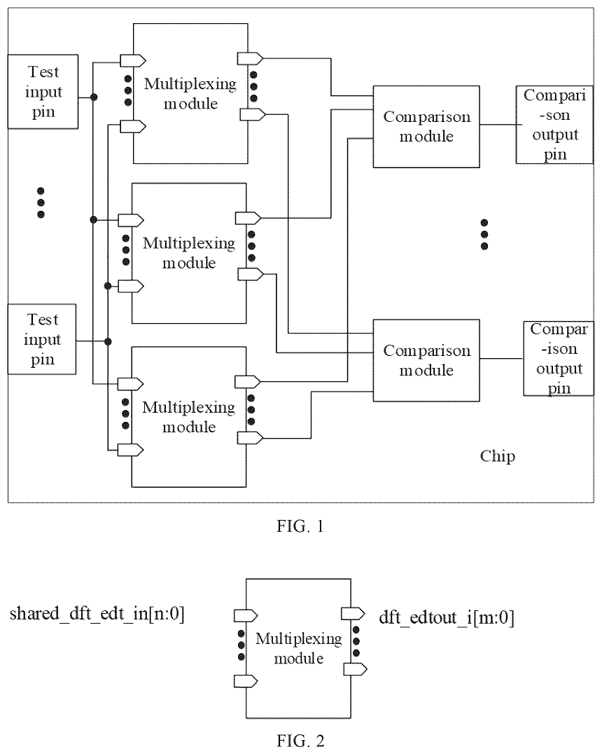

In a first aspect, referring to FIGS. 1 to 6, an embodiment of the present disclosure provides a chip.

An embodiment of the present disclosure provides a relatively independently packaged chip with data processing capability, including but not limited to a logic chip, a network chip, and the like.

Referring to FIG. 1, in an embodiment, the chip of the present disclosure may include: a plurality of structurally identical multiplexing modules, each of which has a module input and a module output; a test input pin connected to module inputs of the multiplexing modules and configured to input a test signal into the module inputs; a comparison module provided with an input connected to module outputs of the multiplexing modules, and an output, where the comparison module is configured to receive and compare result signals output at the module outputs of the respective multiplexing modules for the test signal, and output, at the output of the comparison module, a comparison result indicating whether the result signals of all the module outputs connected thereto are completely the same; and a comparison output pin connected to the output of the comparison module and configured to output a signal representing the comparison result.

The chip provided in the embodiments of the present disclosure may be divided into a plurality of modules, where some of the modules have identical structure and function, which are referred to as multiplexing modules.

For example, in a multi-core chip, a plurality of identical logic cores, i.e., a plurality of multiplexing cores (multiplexing modules), may be formed by a wrapper chain technology.

The chip is further provided with a plurality of pins (i.e., I/O ports, such as pins) for external information interaction, where some of the pins are test input pins configured to receive a test signal and connected to module inputs to transmit the received test signal to the module inputs (e.g., module input pins), so that each multiplexing module is operated based on the received test signal and generates a corresponding result signal at a module output thereof.

In some embodiments, the test input pins are connected to the module inputs at the same position of the multiplexing modules, respectively, and configured to synchronously input the same test signal to the connected module inputs.

Referring to FIG. 1, as an implementation of the embodiment of the present disclosure, each test input pin may be connected to the module inputs at the same position of a plurality of multiplexing modules at the same time, that is, a shared-input technology is employed, so that the same test signal can be received at the module inputs at the same position of all multiplexing modules synchronously by simply inputting the test signal into one test input pin, and then the multiplexing modules will operate synchronously and generate their respective result signals synchronously.

It will be appreciated that instead of using the shared-input technology, it is also possible that each test input pin is connected to only one module input; and in this case, the same test signal needs to be input to a plurality of test input pins corresponding to the module inputs of the multiplexing modules during testing simultaneously.

The test signal may be a test pattern generated by automatic test pattern generation (ATPG), i.e., a signal composed of a series of 0's and 1's. Accordingly, each multiplexing module generates a result pattern, which is also a signal composed of a series of 0's and 1's, based on the test pattern.

When the multiplexing module has no fault, the generated result pattern “should” be a standard signal, namely a standard pattern; and if the multiplexing module has a fault, the generated result pattern may be different from the standard pattern in one or more bits.

Further, the ATPG-based test may employ scan chains which may be designed according to the requirements of Design for Test (DFT). The scan chain is a structure in which functional registers are replaced by scan registers connected in series to form a chain, where a multiplexer (MUX) is added, so that a test signal can be effectively transmitted via the scan chain, and a result signal output from a tested device can be received, thereby implementing testing. Under the control of a MUX selection signal (scan_enable) of the scan register, the scan chain typically has two working modes, i.e., a functional mode and a test mode; In the functional mode, the scan register, which executes the function of a register, is configured to store data of a combinational logic and work based on an original structure; while in the test mode, a test signal is sequentially input through the scan register in a shifting mode, and then a test result is obtained and output via the scan chain in a shifting mode.

Furthermore, as the chip scale is larger and larger, the chip testing process consumes more time and involves higher cost, and therefore, scan chain compression, such as EDT compression of a Tessent tool, can be adopted, where an original larger scan chain can be changed into a plurality of shorter scan chains, thereby reducing the testing time and cost.

Referring to FIG. 1, the chip provided in the embodiments of the present disclosure further includes comparison modules each connected to the module outputs of the multiplexing modules, so that the result signals generated by the multiplexing modules based on the test signal can be received to compare and determine whether all the result signals are completely the same, and then the corresponding comparison result is generated (for example, 0 indicates that all the result signals are completely the same, and 1 indicates that at least one of the result signals is different) and output from a comparison output pin.

Since the structures of all multiplexing modules should be identical theoretically, when the same test signal is received by the plurality of multiplexing modules at the same time, the result signals generated at the module outputs of all multiplexing modules should also be completely the same if all the multiplexing modules are fault-free; and if the result signals are not completely the same, it indicates that not all multiplexing modules have an identical structure, that is, there is at least one faulty (structurally different) multiplexing module.

It will be appreciated that in fact, each multiplexing module may be provided with a plurality of module inputs and a plurality of module outputs, different module inputs of the same multiplexing module may need different test signals, and different module outputs of the same multiplexing module may generate different result signals.

Therefore, each test input pin should be connected to the same module input of each multiplexing module (for example, all connected to an a^{th} module input), and each comparison module should also be connected to the same module output of each multiplexing module (for example, all connected to a b^{th} module output), and the result signals at these same module outputs are compared.

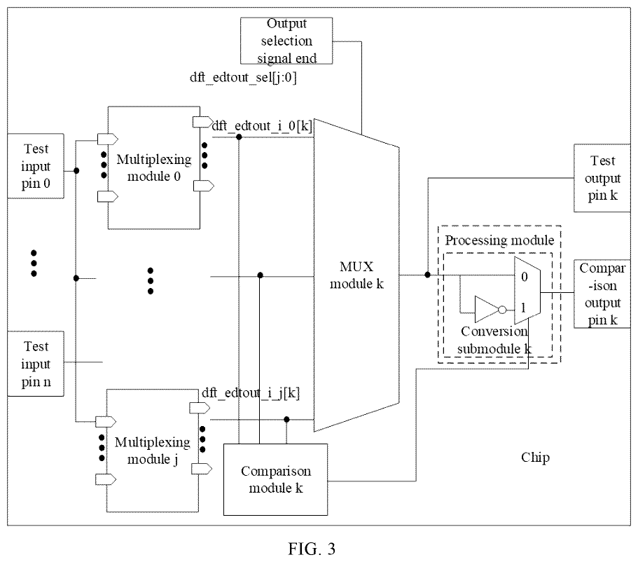

For example, referring to FIG. 2, each multiplexing module may have (n+1) module inputs, i.e., shared_dft_edt_in[n: 0], and (m+1) module outputs, i.e., dft_edtout_i[m: 0]. Therefore, referring to FIG. 3, the chip has (n+1) test input pins (e.g., EDT input pins) in total, and (m+1) comparison modules and (m+1) compare output pins, and may further have (m+1) test output pins (e.g., EDT output pins) as described later, (m+1) multiplexer modules, and the like.

Referring to FIG. 3, the chip may include (j+1) multiplexing modules in total, so the module outputs of all multiplexing modules are dft_edtout_i_0[m: 0] to dft_edtout_i_j[m: 0]; and a k^{th} comparison module, a k^{th} comparison output pin, a k^{th} test output pin and a k^{th} multiplexer module are connected to the module outputs dft_edtout_i_0[k] to dft_edtout_i_j[k].

It will be appreciated that in addition to the test input pin and the comparison module, the module input and module output of each multiplexing module may be further connected to other conventional structures in the chip; and further, the chip may include other pins for inputting and outputting signals during normal operation, and the like.

The chip provided in the embodiments of the present disclosure is internally provided with a comparison module configured to compare signals generated by a plurality of multiplexing modules to obtain a comparison result indicating whether all the signals are the same. Since the multiplexing modules have the same structure, when the same test signal is input to the multiplexing modules through their respective test input pins, the generated result signals should also be the same theoretically. If the result signals are not the same, it indicates that a multiplexing module with a different structure is present. Therefore, whether the chip has a fault can be judged to a certain extent by analyzing the comparison result (for example, if the comparison result shows that there is difference in the result signals generated by the multiplexing modules, it indicates that at least one or more multiplexing modules have faults) instead of outputting the result signals of all the multiplexing modules. Therefore, fewer pins of the chip are needed, the structure is simplified, and the testing process is simpler and faster.

In some embodiments, the chip provided in the embodiments of the present disclosure further includes: a test output pin connected to the module output and configured to output the result signal at the module output.

As discussed above, the comparison result may be used to determine whether all multiplexing modules are completely the same, but not to determine whether a single multiplexing module is normal. Therefore, referring to FIG. 3, the chip provided in the embodiments of the present disclosure may be further provided with a test output pin, which may directly output a result (result signal) generated by the operation of the multiplexing module itself, so that whether the corresponding multiplexing module itself has a fault can be directly determined by analyzing the result signal.

In some embodiments, the chip further includes a multiplexer module provided with a plurality of inputs, an output and a control end. The plurality of inputs of the multiplexer module are connected to a plurality of module outputs. The control end of the multiplexer module is connected to an output selection signal end. The multiplexer module is configured to select, based on a signal at the output selection signal end, the module output in communication with the output of the multiplexer module.

In some embodiments, when the chip further includes a test output pin, the test output pin is connected to the output of the multiplexer module.

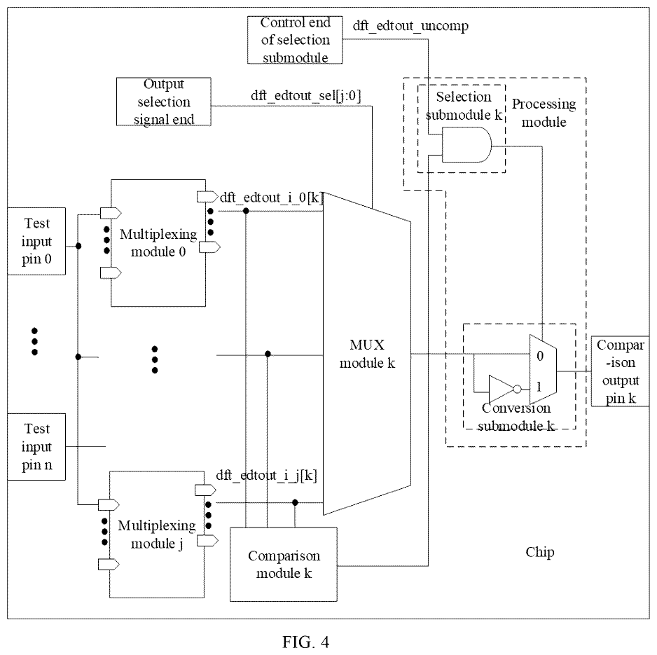

Referring to FIGS. 3 and 4, as an implementation of the embodiment of the present disclosure, the chip may further include a multiplexer (MUX) module, and based on the signal (dft_edtout_sel[j: 0]) at the output selection signal end, the multiplexer module may be enabled to “select” one of the plurality of module outputs connected thereto to be connected with its output (or output end), that is, to select a result signal as its output.

Further, referring to FIG. 3, when the test output pin as described above is provided, the test output pin may be connected to the output of the multiplexer module. In other words, the multiplexer module may select the result signal of “which” multiplexing module is output at the test output pin.

As discussed above, the number of multiplexer modules and the number of test output pins should both correspond to the number of module outputs of a single multiplexing module, i.e., (m+1); and at the same time point, the signal (dft_edtout_sel[j: 0]) at the output selection signal end should generally enable the multiplexer module and the test output pin to output the result signal of one of the (j+1) multiplexing modules.

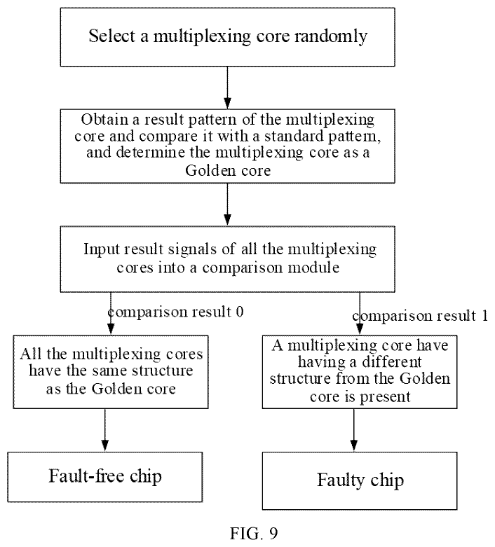

For example, referring to FIG. 9, a certain multiplexing module is selected and result signals generated at module outputs of the multiplexing module are obtained. Based on analysis, if the result signals of the multiplexing module are correct, it can be determined that the multiplexing module is normal (e.g., a Golden core). Further, based on analysis of a comparison result, it can be determined whether all multiplexing modules are the same. If all multiplexing modules are the same, it indicates that all multiplexing modules are normal and the chip has no fault, and if not all multiplexing modules are the same, it indicates that at least one other multiplexing module is different from the Golden core, and the chip has a fault.

It will be appreciated that it is also feasible that the module outputs of only one or more of the multiplexing modules (e.g., one selected multiplexing module) are directly connected to the corresponding test output pins.

Referring to FIG. 3, as an implementation of the embodiment of the present disclosure, the test output pin and the comparison output pin may be two physically independent pins to output the result signal and the comparison result, respectively (including simultaneously).

In some embodiments, the chip provided in the embodiments of the present disclosure further includes: a processing module provided with an input and an output. The input of the processing module is connected to the output of the multiplexer module and the output of the comparison module, respectively. The output of the processing module is connected to the comparison output pin. The processing module is configured to process the result signal output at the output of the multiplexer module connected thereto, and the comparison result output at the output of the comparison module connected thereto, and then output the processed result signal and the processed comparison result to the comparison output pin.

As an implementation of the embodiments of the present disclosure, referring to FIGS. 3 and 4, an output of the multiplexer module (i.e., a result signal, that is, a module output) and an output of the comparison module (i.e., a comparison result) may be respectively connected to the comparison output pin through the processing module, so that the processing module can perform certain processing on the result signal and the comparison result before sending the processed results to the comparison output pin.

In some embodiments, the processing module includes: a selection submodule configured to select whether to output a signal representing the comparison result or the result signal from the comparison output pin.

Referring to FIG. 4, as another implementation of the embodiment of the present disclosure, the processing module may include a selection submodule configured to control the comparison output pin to output a signal representing the comparison result, or output a result signal. In other words, the processing module performs a process of “selecting” the result signal and the comparison result.

Therefore, the comparison result and the result signal may be output in a time-sharing mode through one “common” physical pin (comparison output pin), thereby further reducing the number of pins in the chip.

The selection submodule may adopt various forms.

For example, as a simple manner, the module output (e.g., the output of the multiplexer module) and the output of the comparison module may each be connected to the comparison output pin through a transistor (selection submodule), so that the selected signal can be output by controlling one of the transistors to be turned on and the other to be turned off.

For another example, referring to FIG. 4, the selection submodule is an AND gate, with two inputs connected to the output of the corresponding comparison module and a control end of the selection submodule, respectively, and an output connected to a control end of the multiplexer (MUX) in the corresponding conversion submodule (which will be described later), while the module output (e.g., the output of the multiplexer module) is connected to the comparison output pin through the multiplexer. Therefore, by setting the signal (dft_edtout_uncomp) at the control end of the selection submodule to 0, an output of the AND gate can be ensured to be 0, which means that the signal at the control end of the multiplexer is 0, so that the multiplexer continuously outputs the signal at the module output, i.e., allows the comparison output pin to output a result signal; and by setting the signal (dft_edtout_uncomp) at the control end of the selection submodule to 1, the AND gate may actually output a signal of the comparison result, or the comparison result may be loaded to the control end of the multiplexer, and finally a signal representing the comparison result may be output at the comparison output pin (which will be described later).

In some embodiments, the processing module includes: a conversion submodule configured to generate a converted comparison result from the comparison result and the result signal, as a signal representing the comparison result. When the comparison result indicates that the result signals of all the module outputs are completely the same, the converted comparison result is the same as the signal at the module output, and when the comparison result indicates that the result signals of all the module outputs are not completely the same, the converted comparison result is opposite to the signal at the module output.

As discussed above, the test signal may be a test pattern generated by ATPG, the signal at the corresponding module output is a result pattern, and the analysis process of the result includes comparing the result pattern with a preset standard pattern.

However, the comparison result directly generated by the comparison module is completely determined by whether the signals of the multiplexing module are the same, and completely irrelevant to the original forms of the result pattern and the standard pattern, and thus, it is not convenient to be analyzed.

In view of this, referring to FIGS. 3 and 4, a conversion submodule is provided to convert the comparison result into the form of a “converted comparison result”. In other words, the processing module performs processing of “converting” a form of the comparison result based on the result signal, and the obtained converted comparison result is characterized in that:
(1) if the comparison result at a certain moment indicates that the signals of all the multiplexing modules are the same, corresponding bits of the converted comparison result and the result signal at the module output are the same; and
(2) if the comparison result at a certain moment indicates that the signals of all the multiplexing modules are not the same, corresponding bits of the converted comparison result and the result signal at the module output are inverted to each other.

Therefore, the converted comparison result (representing the comparison result) may be analyzed in a method similar to that for the analysis of the result pattern in the existing art, i.e., comparing the converted comparison result with the standard pattern, and determining, if a certain bit of the converted comparison result is different from that of the standard pattern, that the signal of at least one multiplexing module has an error in the corresponding time.

The conversion submodule may adopt various forms.

For example, referring to FIGS. 3 and 4, the conversion submodule may include the multiplexer described above, the module output (e.g., the output of the multiplexer module) is connected to both inputs of the multiplexer in a direct manner and in an inverted manner (e.g., via a NOT gate unit) respectively, while the control end of the multiplexer is connected to the output of the comparison module (including the direct connection shown in FIG. 3, or the AND gate connection via the selection submodule shown in FIG. 4). Therefore:
(1) when the comparison result is 0 (indicating that the signals of all multiplexing modules are the same), the comparison result controls the multiplexer to directly output a result signal; and
(2) when the comparison result is 1 (indicating that the signal of at least one multiplexing module is different), the comparison result controls the multiplexer to output an inverted result signal.

It will be appreciated that referring to FIG. 4, when both the selection submodule and the conversion submodule are provided, if the selection submodule controls the comparison output pin to output a result signal, then the conversion submodule is disabled; and if the selection submodule controls the comparison output pin to output a signal representing the comparison result, the actual output is a converted comparison result generated by the conversion submodule.

It will be appreciated that the processing module may adopt various forms, for example, including only one of the selection submodule or the conversion submodule, or both, or there may be other submodules; and moreover, the selection submodule, the conversion submodule, and other modules may have other forms, which are not described in detail here.

It will be appreciated that the selection submodule, the conversion submodule, and other modules may have other forms, which are not described in detail here.

In some embodiments, the comparison module includes: a first AND gate unit including a plurality of inputs in one-to-one correspondence with module outputs connected to the comparison module, where each input is connected to the corresponding module output; a first OR gate unit including a plurality of inputs in one-to-one correspondence with module outputs connected to the comparison module, where each input is connected to the corresponding module output; a first XOR gate unit including two inputs connected to an output of the first AND gate unit and an output of the first OR gate unit.

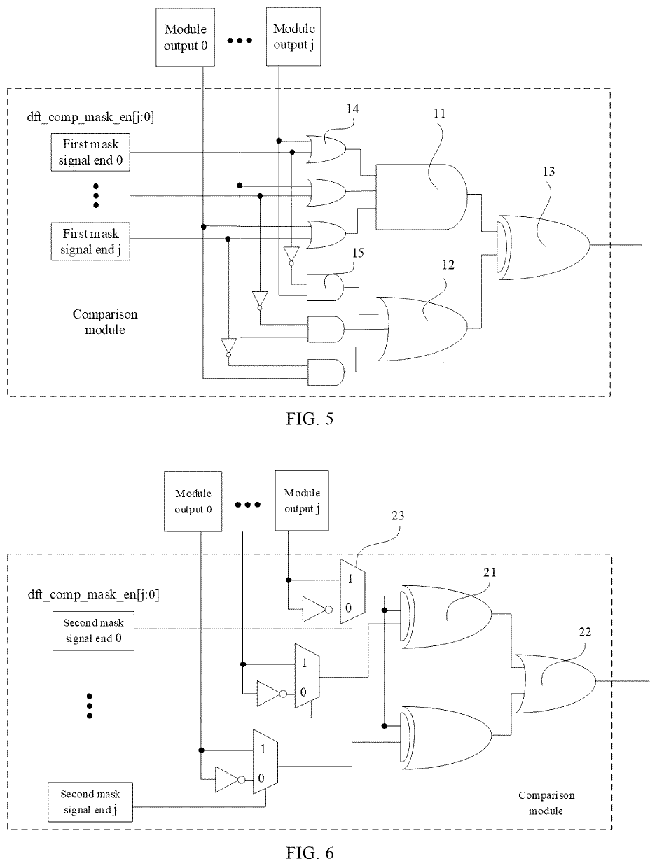

Referring to FIG. 5, as an implementation of the embodiments of the present disclosure, each comparison module may include a first AND gate unit 11 and a first OR gate unit 12, and all module outputs (e.g., (j+1) outputs in total) corresponding to the comparison module are respectively connected to inputs of the first AND gate unit 11 and the first OR gate unit 12, while outputs of the first AND gate unit 11 and the first OR gate unit 12 are further simultaneously connected to inputs of a first XOR gate unit 13.

Therefore, if the signals at all the module outputs are the same (all 1's or all 0's), the outputs of the first AND gate unit 11 and the first OR gate unit 12 are naturally the same (all 1's or all 0's), so that the outputs of the two pass through the first XOR gate unit 13 to generate a comparison result of 0. As long as not all the module outputs output completely the same signal (part 1's and part 0's), it is naturally obtained that the output of the first AND gate unit 11 is 0 and the output of the first OR gate unit 12 is 1, so that the outputs of the two pass through the first XOR gate unit 13 to generate a comparison result of 1.

In some embodiments, the comparison module further includes a second OR gate unit 14 and a second AND gate unit 15 corresponding to at least some of the module outputs. Each second OR gate unit 14 includes two inputs connected to the corresponding module output and a first mask signal end, respectively, and an output connected to one of the inputs of the first AND gate unit 11. Each second AND gate unit 15 includes two inputs inverted to each other connected to the corresponding module output and a first mask signal end, respectively, and an output connected to one of the inputs of the first OR gate unit 12. The second OR gate unit 14 and the second AND gate unit 15 corresponding to the same module output are connected to the same first mask signal end.

In some cases, it may be desired not to compare some of the multiplexing modules, and therefore, information of these multiplexing modules is desired to be “masked” to avoid affecting the comparison module.

For example, if a multiplexing module has been determined to be fault, signals of that multiplexing module may be masked to further analyze whether other multiplexing modules are faulty.

For this purpose, referring to FIG. 5, in the comparison module, a second OR gate unit 14 is further provided between each module output and the corresponding first AND gate unit 11, a second AND gate unit 15 is further provided between each module output and the corresponding first OR gate unit 12, while the other inputs of the second OR gate unit 14 and the second AND gate unit 15 corresponding to the same module output are respectively connected to the same first mask signal end and an inverted end thereof.

It will be appreciated that the term “inverted” in the embodiments of the present disclosure means that the signals connected at the two final positions are inverted, which may be implemented in various manners. For example, referring to FIG. 5, a NOT gate unit may be provided between the first mask signal end and the second AND gate unit 15, or different ports, which always provide inverted signals, may be connected at the two positions.

Meanwhile, two inverted signals are relative concepts rather than absolute concepts. For example, referring to FIG. 5, the NOT gate unit may be actually disposed between the first mask signal end and the second OR gate unit 14, in which case the signal provided by the first mask signal end may be simply inverted.

When a signal at a certain module output needs to be masked, a corresponding signal (dft_comp_mask_en[j: 0]) at the first mask signal end may be set to be 1, so that the output of the second OR gate unit 14 is continuously 1, which will “not affect” the later output of the first AND gate unit 11. Meanwhile, an inverse of the signal at the first mask signal end is 0, so that the output of the second AND gate unit 15 is continuously 0, which will also “not affect” the later output of the first OR gate unit 12.

For a module output that is not desired to be masked, the corresponding signal at the first mask signal end is set to 0, which may be understood as that the presence of the second AND gate unit 15 and the second OR gate unit 14 will “not affect” the result signal at that module output.

In other words, when the signal (dft_comp_mask_en[j: 0]) at the first mask signal end corresponding to the module output is set to be 1, the first AND gate unit 11 and the first OR gate unit 12 can operate based on signals of “other” module outputs without being affected by the signal of that module output. In other words, the signal of the corresponding module output is “masked”.

In some embodiments, the comparison module includes: a plurality of second XOR gate units, where one of the module outputs connected to the comparison module is simultaneously connected to one input of each of the second XOR gate units, while the other module outputs are respectively connected to the other inputs of the second XOR gate units in a one-to-one correspondence manner; and a third OR gate unit including a plurality of inputs connected to outputs of the second XOR gate units, respectively.

Referring to FIG. 6, as another implementation of the embodiments of the present disclosure, the comparison module may include a plurality of second XOR gate units 21 (j second XOR gate units 21), where all the second XOR gate units 21 have one input connected to the same module output (taking a module output j as an example in FIG. 6), while each of the other module outputs (taking module outputs 0 to j−1 as an example in FIG. 6) is connected to the other input of each of the second XOR gate units 21, respectively. Therefore, providing the plurality of second XOR gate units 21 is equivalent to comparing the signal of a selected module output (module output j) with each of signals of other module outputs, respectively. If the results are the same, the outputs of all the second XOR gate units 21 are 0, and then the third OR gate unit 22 can generate a comparison result of 0; and if not all the results are the same, the output of a certain second XOR gate unit 21 will be 1, and the third OR gate unit 22 can generate a comparison result of 1.

In some embodiments, the comparison module further includes a multiplexer unit 23 corresponding to at least one or more of the module outputs; and the module output is connected to two inputs of the corresponding multiplexer unit 23 in a direct manner and in an inverted manner, respectively, an output of the multiplexer unit 23 is connected to the corresponding second XOR gate unit 21, and a control end of the multiplexer unit 23 is connected to a second mask signal end.

The comparison module in the form of FIG. 6 further includes a multiplexer (MUX) unit 23 serving as a mask, while each module output is connected to the multiplexer unit 23 in a direct manner and in an inverted manner (e.g., via a NOT gate unit) at the same time, so that the multiplexer unit 23 can be selected to output an original signal at the module output or an inverted signal thereof based on the signal (dft_comp_mask_en[j: 0]) at the second mask signal end.

Therefore, when the result signal at a certain module output is determined to be in error at a certain time, the corresponding multiplexer unit 23 is controlled, by a signal at the second mask signal end, to output an inverted signal. In other words, the signal entering the second XOR gate unit 21 from the module output is ensured to be correct all the time, so as to shielding the influence of the signal at the module output.

It will be appreciated that the chip may further include other structures, such as a beat logic module upstream of the test output pins (including the shared comparison output pin), a register module directly connected to each module output, a compressor/decompressor in the multiplexing module, and the like, which are not described in detail here.

The effects achieved by the chip provided in the embodiments of the present disclosure are described in detail below,

For example, it is assumed that a chip has 32 multiplexing cores, each multiplexing core having 6 outputs, and the chip has 36 output pins.

Therefore, according to the ATPG testing method in the existing art, a maximum of 36/6=6 multiplexing cores can be tested on the ATE device at a time, so that 32/6~6 tests are required in total, and the time for testing is approximately 6 T (assuming that the time for a single test is T).

However, if the method according to the embodiments of the present disclosure is adopted, testing can be performed only once (if the comparison result and the result signal can be output simultaneously) or twice (if the comparison result and the result signal are output separately), and the testing time is approximately T or 2 T, which is ⅙ or ⅓ of that in the existing art.

Moreover, if the method according to the embodiments of the present disclosure is adopted, only 6 (if the comparison result and the result signal are output in a time-sharing mode from the comparison output pin) or 12 (if the comparison result and the result signal are output from different pins) output pins are actually required, so that the number of output pins actually required is greatly reduced and I/O resources are saved.

In a second aspect, referring to FIGS. 1 to 9, an embodiment of the present disclosure provides a chip testing method.

The chip tested in the method according to the embodiment of the present disclosure includes a plurality of structurally identical multiplexing modules, each of which has a module input and a module output.

It will be appreciated that the chip testing method in the embodiment of the present disclosure may be used to test any chip provided in the embodiments of the present disclosure.

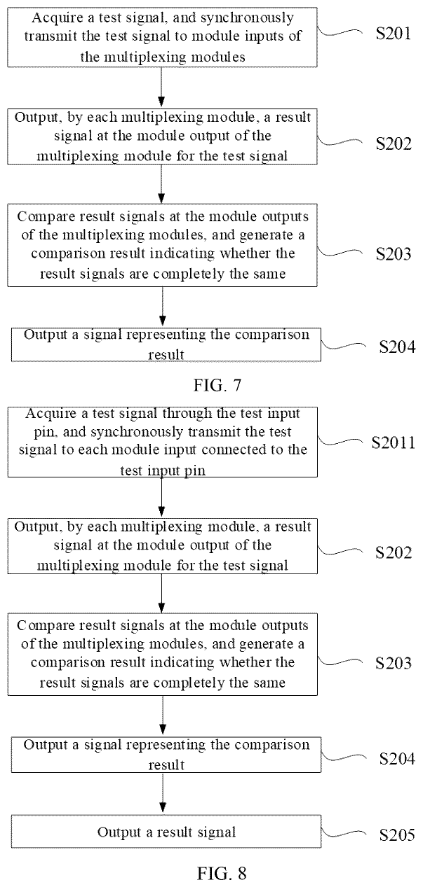

Referring to FIG. 7, the chip testing method in the embodiment of the present disclosure may include the following operations S201 to S204.

At operation S201, acquiring a test signal, and synchronously transmitting the test signal to module inputs of the multiplexing modules.

At operation S202, outputting, by each multiplexing module, a result signal at the module output of the multiplexing module for the test signal.

At operation S203, comparing result signals at the module outputs of the multiplexing modules, and generating a comparison result indicating whether the result signals are completely the same.

At operation S204, outputting a signal representing the comparison result.

In the chip testing method provided in the embodiments of the present disclosure, the chip first acquires a test signal (for example, through a test input), and synchronously transmits the test signal to module inputs of the multiplexing modules, so that the multiplexing modules synchronously operate based on the test signal and output result signals at their respective module outputs. Then, the chip may compare result signals at the module outputs of the multiplexing modules to generate a comparison result (e.g., in the comparison module) indicating whether the result signals are all the same. Finally, the chip may output a signal representing the comparison result (e.g., through the comparison output pin).

Therefore, whether the multiplexing modules of the chip are completely the same (i.e., the consistency of the multiplexing modules) can be determined by analyzing the signal representing the comparison result.

In some embodiments, the test signal includes a test pattern generated by ATPG.

In some embodiments, the chip further includes test input pin, wherein each test input pin is connected to the module input of each multiplexing module at the same position. Referring to FIG. 8, acquiring the test signal, and synchronously transmitting the test signal to the module inputs of the multiplexing modules (S201) includes: operation S2011, acquiring a test signal through the test input pin, and synchronously transmitting the test signal to each module input connected to the test input pin.

When the chip adopts the shared-input technology, the test signal acquired through one test input pin can be synchronously transmitted to the module inputs at the same position of the multiplexing modules.

It will be appreciated that it is also feasible to not use the shared-input technology, and in this case, the same test signal needs to be simultaneously provided to a plurality of test input pins corresponding to the module inputs of the multiplexing modules.

In some embodiments, referring to FIG. 8, after outputting, by each multiplexing module, the result signal at the module output of the multiplexing module for the test signal (S202), the method further includes: operation S205, outputting a result signal.

During the chip testing process, the chip may further output (e.g., through the test output pin, or through the comparison output pin in a time-sharing mode) a result signal (e.g., a result pattern) of a specific multiplexing module, so that by analyzing the result signal (e.g., comparing the result pattern with a standard pattern), whether the corresponding multiplexing module has a fault, i.e., the correctness of the multiplexing module, can be determined.

It will be appreciated that the above process for determining the consistency of the multiplexing modules and the process for determining the correctness of the multiplexing module are relatively independent, and the execution order, relationship and the like of the two processes are not necessarily limited.

For example, the processes of determining the consistency and correctness of the multiplexing module are performed in two procedures. That is, the test signal is input twice, and the comparison result and the result signal are obtained by the comparison output pin respectively. The obtaining order of the two is not necessarily limited.

Alternatively, when the chip has both the comparison output pin and the test output pin separately provided, the comparison result and the result signal may be obtained simultaneously in the case of inputting the test signal once.

For another example, referring to FIG. 9, a multiplexing module (multiplexing core) is randomly selected, and a result signal (result pattern) corresponding to the multiplexing module is obtained and compared with a standard result (standard pattern). If the result signal is the same as the standard result, it is determined that the multiplexing module is normal (e.g., is a Golden core). Then, the result signals of all the multiplexing modules are input into a comparison module to analyze whether the comparison result is 0 or 1. In the case of 0, it indicates that all the multiplexing modules have the same structure (i.e., the same structure as the Golden core), and the chip can be determined to be fault-free. In the case of 1, it indicates that not all the multiplexing modules have the same structure (i.e., one or more are different from the Golden core), and the chip can be determined to be faulty.

Alternatively, it is also possible to test whether all multiplexing modules are the same first, and then different subsequent operations are performed according to different results:
(1) If all multiplexing modules are the same, the chips can be approximately considered to be fault-free; or, one multiplexing module may be further selected for correctness test, and if the multiplexing module is normal, it is determined that the chip has no fault.
(2) If not all multiplexing modules are the same, it may be directly determined that the chip has a fault and the process is ended (if fault location not required); or, the correctness of one or more multiplexing modules can be further detected to implement fault location.

Those of ordinary skill in the art will appreciate that all or some operations, function modules/units in the system and apparatus disclosed above may be implemented as software, firmware, hardware, and suitable combinations thereof.

In a hardware implementation, the division between the function modules/units mentioned in the above description does not necessarily correspond to the division of physical components; for example, one physical component may have multiple functions, or one function or operation may be performed cooperatively by several physical components.

The present disclosure has disclosed exemplary embodiments, and although specific terms are employed, they are used and should be interpreted merely in a generic and descriptive sense, not for purposes of limitation. In some instances, as would be apparent to one skilled in the art, features, characteristics and/or elements described in connection with a particular embodiment may be used alone or in combination with features, characteristics and/or elements described in connection with another embodiment, unless expressly stated otherwise. It will, therefore, be understood by those skilled in the art that various changes in form and details may be made therein without departing from the scope of the present disclosure as set forth in the appended claims.

1. A chip, comprising:
a plurality of structurally identical multiplexing modules, each of which has a module input and a module output;
a test input pin connected to module inputs of the plurality of multiplexing modules and configured to input a test signal into the module inputs;
a comparison module provided with an input connected to module outputs of the plurality of multiplexing modules, and an output, wherein the comparison module is configured to receive and compare result signals output at the module outputs of the plurality of multiplexing modules for the test signal, and output, at the output of the comparison module, a comparison result indicating whether the result signals of all the module outputs connected thereto are completely the same; and
a comparison output pin connected to the output of the comparison module and configured to output a signal representing the comparison result.

2. The chip according to claim 1, wherein
each test input pin is connected to the module inputs at a same position of the plurality of multiplexing modules, respectively, and configured to synchronously input a same test signal to the connected module inputs.

3. The chip according to claim 1, further comprising:
a test output pin connected to the module output and configured to output the result signal at the module output.

4. The chip according to claim 1, further comprising:
a multiplexer module provided with a plurality of inputs, an output and a control end; wherein the plurality of inputs of the multiplexer module are connected to the module outputs, the control end of the multiplexer module is connected to an output selection signal end, and the multiplexer module is configured to select, based on a signal at the output selection signal end, the module output in communication with the output of the multiplexer module.

5. The chip according to claim 4, further comprising:
a test output pin connected to the output of the multiplexer module.

6. The chip according to claim 4, further comprising:
a processing module provided with an input and an output, wherein the input of the processing module is connected to the output of the multiplexer module and the output of the comparison module, respectively, the output of the processing module is connected to the comparison output pin, and the processing module is configured to process the result signal output at the output of the multiplexer module connected thereto, and the comparison result output at the output of the comparison module connected thereto, and output the processed result signal and the processed comparison result to the comparison output pin.

7. The chip according to claim 6, wherein the processing module comprises:
a selection submodule configured to select whether to output a signal representing the comparison result or the result signal from the comparison output pin.

8. The chip according to claim 6, wherein the processing module comprises:
a conversion submodule configured to generate a converted comparison result from the comparison result and the result signal, as the signal representing the comparison result; wherein when the comparison result indicates that the result signals of all the module outputs are completely the same, the converted comparison result is the same as the result signal at the module output, and when the comparison result indicates that the result signals of all the module outputs are not completely the same, the converted comparison result is opposite to the result signal at the module output.

9. The chip according to claim 1, wherein the comparison module comprises:
a first AND gate unit comprising a plurality of inputs in one-to-one correspondence with the module outputs connected to the comparison module, wherein each input is connected to a corresponding module output;
a first OR gate unit comprising a plurality of inputs in one-to-one correspondence with the module outputs connected to the comparison module, wherein each input is connected to a corresponding module output; and
a first XOR gate unit comprising two inputs connected to an output of the first AND gate unit and an output of the first OR gate unit, respectively.

10. The chip according to claim 9, wherein the comparison module further comprises a second OR gate unit and a second AND gate unit corresponding to at least one of the module outputs;
each second OR gate unit comprises two inputs connected to a corresponding module output and a first mask signal end, respectively, and an output connected to one of the plurality of inputs of the first AND gate unit; and
each second AND gate unit comprises two inputs inverted to each other and connected to a corresponding module output and a first mask signal end, respectively, and an output connected to one of the plurality of inputs of the first OR gate unit;
wherein the second OR gate unit and the second AND gate unit corresponding to a same module output are connected to a same first mask signal end.

11. The chip according to claim 1, wherein the comparison module comprises:
a plurality of second XOR gate units, wherein one of the module outputs connected to the comparison module is simultaneously connected to one input of each of the plurality of second XOR gate units, while module outputs other than the one module output are respectively connected to inputs of the plurality of second XOR gate units other than the one input in a one-to-one correspondence manner; and
a third OR gate unit comprising a plurality of inputs connected to outputs of the plurality of second XOR gate units, respectively.

12. The chip according to claim 11, wherein the comparison module further comprises a multiplexer unit corresponding to at least one of the module outputs; and
the module output is connected to two inputs of a corresponding multiplexer unit in a direct manner and in an inverted manner, respectively, an output of the multiplexer unit is connected to a corresponding second XOR gate unit, and a control end of the multiplexer unit is connected to a second mask signal end.

13. A chip testing method, wherein the chip comprises a plurality of structurally identical multiplexing modules, each of which has a module input and a module output, and the method comprises:
acquiring a test signal, and synchronously transmitting the test signal to module inputs of the plurality of multiplexing modules;
outputting, by each of the plurality of multiplexing modules, a result signal at the module output of the multiplexing module for the test signal;
comparing result signals at the module outputs of the plurality of multiplexing modules, and generating a comparison result indicating whether the result signals are completely the same; and
outputting a signal representing the comparison result.

14. The method according to claim 13, wherein the chip further comprises a test input pin, wherein each test input pin is connected to the module input of each multiplexing module at a same position; and
acquiring the test signal, and synchronously transmitting the test signal to the module inputs of the plurality of multiplexing modules comprises; acquiring a test signal through the test input pin, and synchronously transmitting the test signal to each module input connected to the test input pin.

15. The method according to claim 13, wherein after outputting, by each of the plurality of multiplexing modules, the result signal at the module output of the multiplexing module for the test signal, the method further comprises:
outputting the result signal.

16. The method according to claim 13, wherein
the test signal comprises a test pattern generated by automatic test pattern generation (ATPG).
